(19) United States
(12) Patent Application Publication
(10) Pub. No.: US 2017/0295656 A1
(43) Pub. Date: Oct. 12, 2017

(54) ELECTRONIC DEVICE

(71) Applicant: TPV-INVENTA TECHNOLOGY CO.,LTD., Taipei City (TW)

(72) Inventor: Pei-Ju TSAI, Taipei City (TW)

(73) Assignee: TPV-INVENTA TECHNOLOGY CO.,LTD., Taipei City (TW)

(21) Appl. No.: 15/189,351

(22) Filed: Jun. 22, 2016

(30) Foreign Application Priority Data
Apr. 8, 2016 (TW) 105204877

(51) Int. Cl. H05K 5/02; F16M 13/06; F16M 13/00

(52) U.S. Cl. CPC H05K 5/023; F16M 13/005; F16M 13/06; H05K 5/0234

(57) ABSTRACT

An electronic device includes a main body and a movable frame. The main body has a side edge. The movable frame is movable among a closed position, a grab position and a support position. The movable frame includes a first stand member and a second stand member. The first stand member has a first end and a second end which are opposite to each other. The first end is pivoted to the main body. The second stand member has a handle. The second stand member is slidably disposed on the first stand member.

### CROSS-REFERENCE TO RELATED APPLICATIONS

This non-provisional application claims priority under 35 U.S.C. §119(a) on Patent Application No(s). 105204877 filed in Taiwan, R.O.C. on Apr. 8, 2016, the entire contents of which are hereby incorporated by reference.

### TECHNICAL FIELD

The disclosure relates to an electronic device, more particularly to a portable electronic device.

### BACKGROUND

With the development of technology, electronic devices, such as desk top computers, note book computers, tablets computers or smart phones, are widely used in daily life. Take the tablet computer as an example, the tablet computer is portable and usually has a smooth and simple appearance. In addition, the tablet computer is usually equipped with a supporting stand. The supporting stand is disposed on the back of the tablet computer for positioning the tablet computer at a comfortable viewing angle.

### SUMMARY

The present disclosure provides an electronic device which is easy for users to carry or move and has light and thin in design.

One embodiment of the disclosure provides an electronic device including a main body and a movable frame. The main body has a side edge. The movable frame is movable among a closed position, a grab position and a support position. The movable frame includes a first stand member and a second stand member. The first stand member has a first end and a second end which are opposite to each other. The first end is pivoted to the main body. The second stand member has a handle. The second stand member is slidably disposed on the first stand member. When the movable frame is located at the closed position, the handle is relatively close to the first end, the handle is located between the first end and the side edge, and the second end is closed to the main body. When the movable frame is located at the grab position, the handle is relatively away from the first end, the second end is close to the main body, and the side edge is located between the first end and the handle. When the movable frame is located at the support position, the handle is relatively close to the first end, the second end is relatively away from the main body, and the first stand member and the second stand member together form a supporting stand.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a perspective view of an electronic device having a movable frame located at a closed position according to one embodiment of the disclosure;

FIG. 2 is a perspective view of the electronic device in FIG. 1 when the movable frame is located at a support position;

FIG. 3 is a perspective view of the electronic device in FIG. 1 when the movable frame is located at a grab position;

FIG. 4 is a perspective view of an electronic device having a movable frame located at a grab position according to another embodiment of the disclosure; and

FIG. 5 is a perspective view of an electronic device having a movable frame located at a grab position according to yet another embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

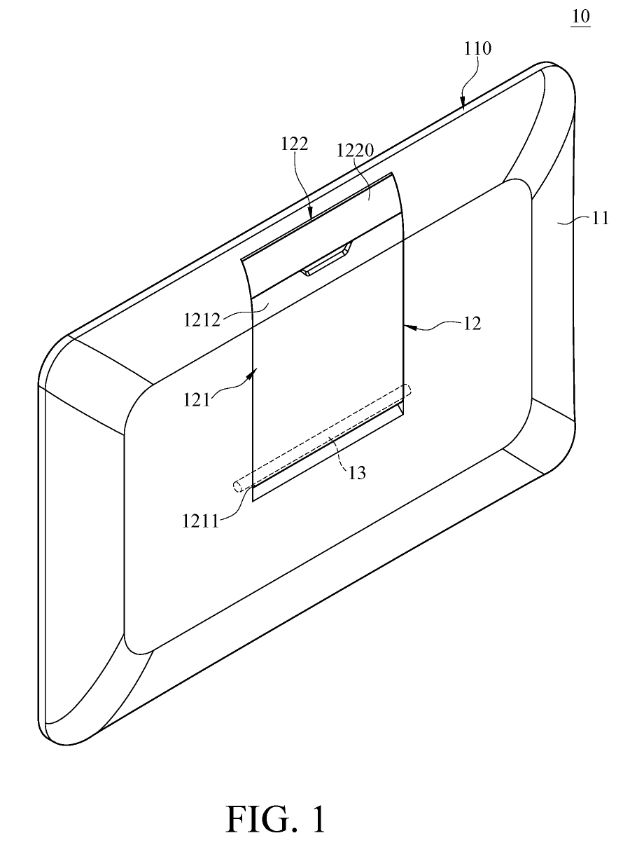

Please refer to FIG. 1, which is a perspective view of an electronic device having a movable frame located at a closed position according to one embodiment of the disclosure. In this embodiment, an electronic device 10 is provided. The electronic device 10 includes a main body 11, a movable frame 12 and a damping hinge 13. The main body 11 has a side edge 110. The movable frame 12 includes a first stand member 121 and a second stand member 122. The first stand member 121 has a first end 1211 and a second end 1212 which are opposite to each other. The first end 1211 of the first stand member 121 is pivoted to the main body 11 via the damping hinge 13. The damping hinge 13, is for example, a hinge having a damping device for damping the hinge movement or a hinge performing a damping function. The second stand member 122 has a handle 1220.

The second stand member 122 is slidably disposed on the first stand member 121, thus the handle 1220 of the second stand member 122 is able to be moved close to or away from the first end 1211 of the first stand member 121. The first stand member 121 is rotatable relative to the main body 11, thus the second end 1212 of the first stand member 121 is able to be moved close to or away from the main body 11. In this and other embodiments, the movable frame 12 is able to be moved among a closed position, a grab position and a support position according to the relative position among the main body, the first stand member and the second stand member.

As shown in FIG. 1, when the movable frame 12 is located at the closed position, the handle 1220 of the second stand member 122 is close to the first end 1211 of the first stand member 121. The handle 1220 is located between the first end 1211 and the side edge 110 of the main body 11. The second end 1212 of the first stand member 121 is close to the main body 11.

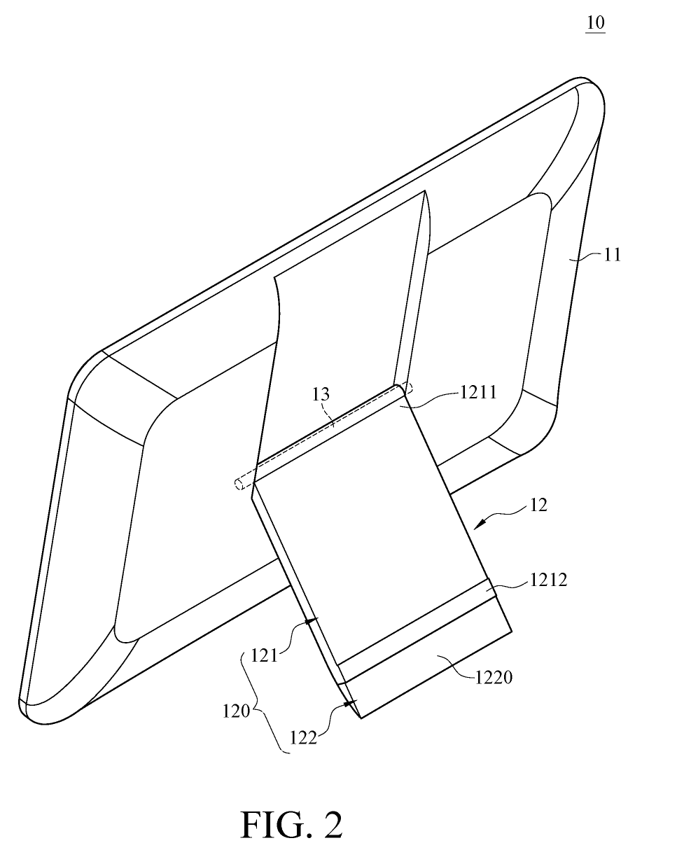

Please refer to FIG. 2, which is a perspective view of the electronic device in FIG. 1 when the movable frame is located at a support position. When the movable frame 12 is located at the support position, the handle 1220 of the second stand member 122 is close to the first end 1211 of the first stand member 121, but the second end 1212 of the first stand member 121 is relatively away from the main body 11 by comparing to the position of the second end 1212 in FIG. 1. In the support position, the first stand member 121 and the second stand member 122 together form a supporting stand 120. The damping hinge 13 is able to provide damping function for maintaining an angle between the first stand member 121 and the main body 11, thereby supporting the main body 11 and preventing the main body 11 from falling. In this embodiment, when the movable frame 12 is located at the support position, the angle between the first stand member 121 and the movable frame 12 is obtuse, but the present disclosure is not limited thereto. In other embodiments, when the movable frame 12 is located at the support position, the said angle between the first stand member 121 and the movable frame 12 can be acute or a right angle. In addition, in other embodiments, the damping hinge 13 can be replaced with another type of hinge or connecting member.

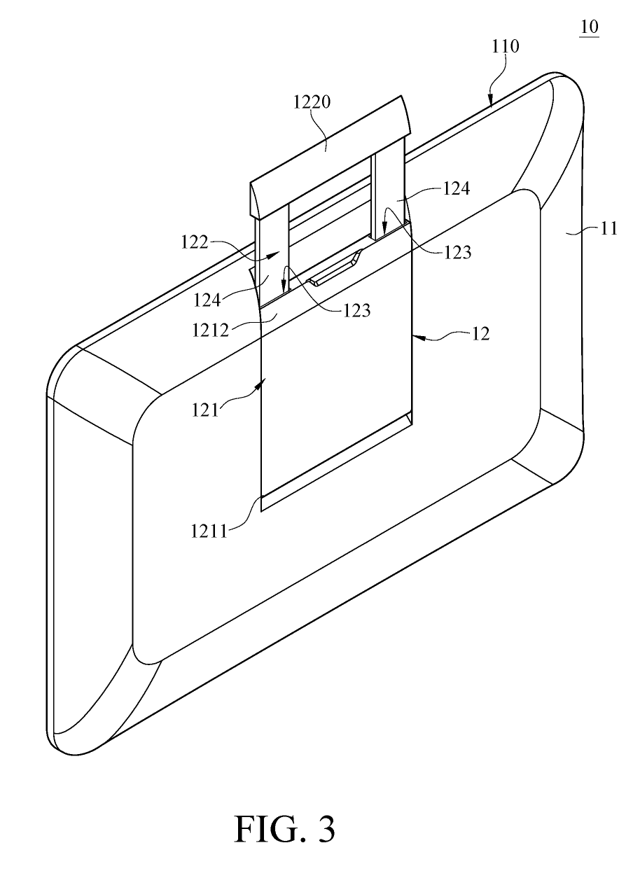

Please refer to FIG. 3, which is a perspective view of the electronic device in FIG. 1 when the movable frame is located at a grab position. When the movable frame 12 is located at the grab position, the handle 1220 of the second stand member 122 is relatively away from the first end 1211 of the first stand member 121 by comparing to the position of the handle 1220 in FIG. 1, the second end 1212 is relatively close to the main body 11 by comparing to the position of the second end 1212 in FIG. 2, and the side edge 110 is located between the first end 1211 and the handle 1220. Thus, there is a through hole formed between the handle 1220 and the side edge 110 so that human fingers can grab the handle 1220 by penetrating through the through hole.

In addition, the movable frame 12 further includes two slots 123 and two slidable members 124. In this embodiment, the two slots 123 are located on the first stand member 121. The two slidable members 124 are located on the second stand member 122. The two slidable members 124 are slidably disposed in the two slots 123, respectively. Thus, the two slidable members 124 can be guided into the two slots 123. In this embodiment, the handle 1220 is a U-shaped handle. However, the present disclosure is not limited to the configuration of the handle 1220, the quantity of the slots 123 and the quantity of the slidable members 124.

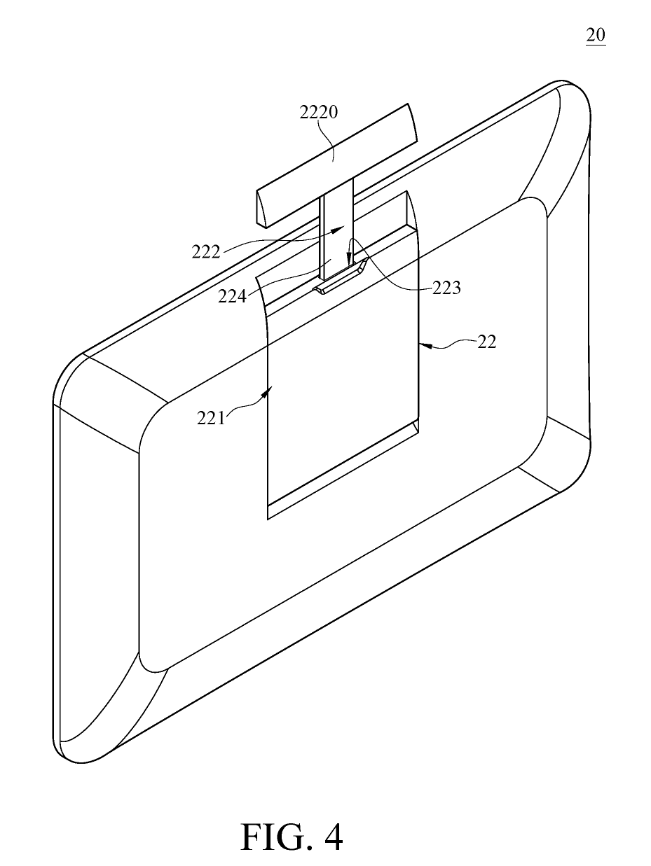

For example, please refer to FIG. 4, which is a perspective view of an electronic device having a movable frame located at a grab position according to another embodiment of the disclosure. In this embodiment, only differences between the present embodiment and the previous embodiment will be explained because the two embodiments are similar to each other.

In this embodiment, an electronic device 20 is provided. The electronic device 20 includes a movable frame 22. The movable frame 22 includes a first stand member 221 and a second stand member 222. The second stand member 222 has a handle 2220. The second stand member 222 is slidably disposed on the first stand member 221. The movable frame 22 further includes a slot 223 and a slidable member 224. The slot 223 is located on the first stand member 221. The slidable member 224 is located on the second stand member 222. The slidable member 224 is slidably disposed in the slot 223, thus the slidable member 224 can be guided into the slot 223. In addition, the handle 2220 of the second stand member 222 is a T-shaped handle.

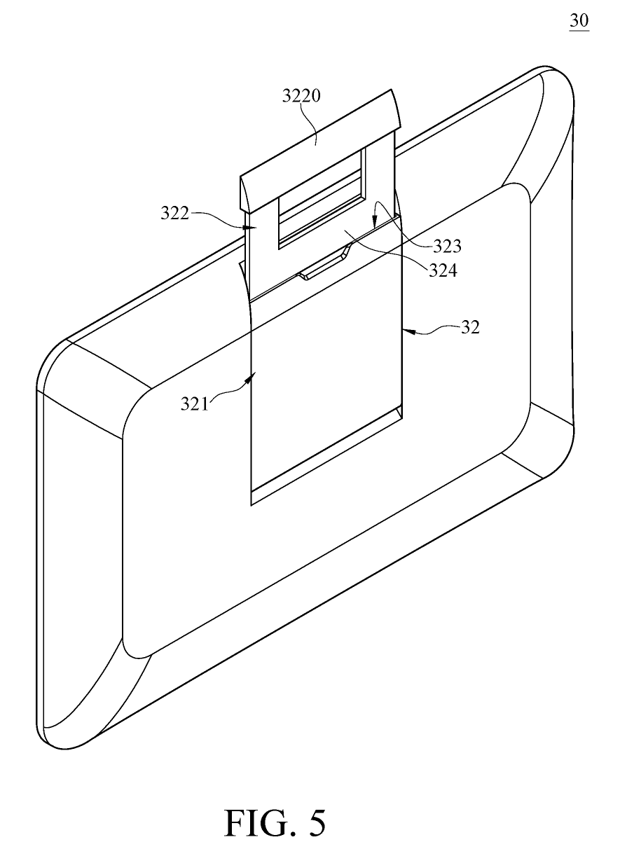

Then, please refer to FIG. 5, which is a perspective view of an electronic device having a movable frame located at a grab position according to yet another embodiment of the disclosure. In this embodiment, only differences between the present embodiment and the previous embodiment will be explained because the two embodiments are similar to each other.

In this embodiment, an electronic device 30 is provided. The electronic device 30 includes a movable frame 32. The movable frame 32 includes a first stand member 321 and a second stand member 322. The second stand member 322 has a handle 3220. The second stand member 322 is slidable disposed on the first stand member 321. The movable frame 22 further includes a slot 323 and a slidable member 324. The slot 323 is located on the first stand member 321. The slidable member 324 is located on the second stand member 322. The slidable member 324 is slidably disposed in the slot 323, thus the slidable member 324 can be guided into the slot 323. In addition, the handle 3220 of the second stand member 222 is a U-shaped handle.

According to the electronic device as discussed above, since the movable frame is able to be moved among the closed position, the grab position and the support position according to the relative positions among the main body, the first stand member and the second stand member, the movable frame can provide several different functions such as supporting the electronic device and enabling the user to carry or move the electronic device. Hence, the electronic device having such multifunctional movable frame is light and thin in design.

Furthermore, when the movable frame is located at the grab position, the side edge is located between the first end and the handle so that a through hole is formed between the handle and the side edge. Thus, human fingers can grab the handle firmly and comfortable by penetrating through the through hole so that the electronic device is not easily dropped. When the movable frame is located at the support position, the first stand member and the second stand member together form the supporting stand for allowing the electronic device to be positioned at a comfortable viewing angle. When the movable frame is located at the closed position, the electronic device is simple and smooth in appearance.

What is claimed is:

1. An electronic device, comprising:
a main body having a side edge; and
a movable frame being movable among a closed position, a grab position and a support position, the movable frame comprising:
a first stand member having a first end and a second end which are opposite to each other, and the first end pivoted to the main body; and
a second stand member having a handle, and the second stand member slidably disposed on the first stand member;
wherein when the movable frame is located at the closed position, the handle is relatively close to the first end, the handle is located between the first end and the side edge, and the second end is closed to the main body;
wherein when the movable frame is located at the grab position, the handle is relatively away from the first end, the second end is close to the main body, and the side edge is located between the first end and the handle;
wherein when the movable frame is located at the support position, the handle is relatively close to the first end, the second end is relatively away from the main body, and the first stand member and the second stand member together form a supporting stand.

2. The electronic device according to claim 1, wherein the movable frame further comprises at least one slot and at least one slidable member, the at least one slot is located on the first stand member, the at least one slidable member is located on the second stand member, and the at least one slidable member is slidably disposed in the at least one slot.

3. The electronic device according to claim 1, wherein the handle is a T-shaped handle.

4. The electronic device according to claim 1, wherein the handle is a U-shaped handle.

5. The electronic device according to claim 1, further comprising a damping hinge, the first stand member pivoted to the main body via the damping hinge, wherein when the movable frame is located at the support position, an angle between the first stand member and the main body is maintained by the damping hinge.
